(19) United States
(12) Patent Application Publication
(10) Pub. No.: US 2008/0316608 A1
(43) Pub. Date: Dec. 25, 2008

(54) Micro-lens fabricated from semiconductor wafer

(75) Inventor: Hironori Sasaki, Tokyo (JP)

Correspondence Address: RABIN & Berdo, PC, 1101 14TH STREET, NW, SUITE 500, WASHINGTON, DC, 20005, US

(73) Assignee: OKI ELECTRONIC INDUSTRY CO., LTD., Tokyo (JP)

(21) Appl. No.: 12/155,292

(22) Filed: Jun. 2, 2008

(30) Foreign Application Priority Data
Jun. 23, 2007 (JP) 2007-165700

(51) Int. Cl. G02B 13/00; H01L 23/544

(52) U.S. Cl. 359/642; 257/797; 257/E23.179

(57) ABSTRACT

A purpose of the present invention is to provide a micro-lens enabling in a simple and highly accurate manner to assess an amount of misalignment with an optical axis generated by an error in a process of manufacturing a micro-lens.

According to the present invention, the micro-lens manufactured using a semiconductor lens is provided with a lens portion, a peripheral portion located outside the lens portion and a mark for assessment formed near the peripheral portion during a process of manufacturing the lens portion.

### CROSS REFERENCE TO RELATED APPLICATION

This application claims the priority of Application No. 2007-165700, filed Jun. 23, 2007 in Japan, the subject matter of which is incorporated herein by reference.

### TECHNICAL FIELD OF THE INVENTION

The present invention relates to a micro-lens manufactured using a semiconductor substrate (silicon wafer). In particular, the present invention relates to a method of assessing to determine an error in an external shape in a manufacturing process of the micro-lens.

### BACKGROUND OF THE INVENTION

Optical communication using an optical fiber represented by Fiber To The Home (FTTH) has become widely used. So called an “optical module” configured by aligning a laser as a light source and an optical fiber or an optical fiber and an optical receiver with high accuracy has been proposed.

Patent Document 1 (Japan Patent Publication Number 3696802) disclosed a technology to manufacture a micro-lens with a size in an order of a few hundred micrometers using a lithography and etching technology, which is a semiconductor manufacturing technology. According to Patent Document 1, a semiconductor laser beam source, a micro-lens and an optical fiber are mounted on a common silicon substrate. Use of such a structure allows a beam emitted from a semiconductor laser effectively to couple with the optical fiber.

In Patent Document 1, a peripheral portion of the micro-lens is manufactured in the same diameter as the optical fiber. The peripheral portion of the micro-lens is thus mounted butting against a common V-groove to realize aligning the optical fiber with the optical axis of the micro-lens within the vertical plane.

Accordingly, mounting accuracy of a micro-lens is assured by butting the peripheral portion thereof, for example, against a V-groove so that there is a need to improve manufacturing accuracy of the micro-lens in order to increase mounting accuracy.

FIG. 1 shows the results of calculating alignment tolerance in an optical system disclosed in Patent Document 1. In this calculation, a spot radius of the beam emitted from a laser and a spot radius of the incident light on an optical fiber are assumed to be 1 μm (micro meters) and 4.6 μm (micro meters), respectively. The horizontal is a parameter for an amount of relative misalignment with the optical axis between the laser and the micro-lens in the vertical direction and an amount of relative misalignment with the optical axis between the optical fiber and the micro-lens in the vertical direction, respectively. A coupling efficiency was then calculated using a coupled-mode theory. It is understood from FIG. 1 that requirement for accuracy of alignment between a laser and a micro-lens is in particular stringent so that misalignment of 0.5 μm (micro meters) from the optical axis results in decrease of the coupling efficiency to a range of 1 dB.

In order to satisfy the requirement for such high accuracy in manufacturing, Patent Document 2 (Japan Patent Publication Laid Open Number 2003-161811) disclosed a means of manufacturing a lens portion of a micro-lens in the photolithography and etching processes followed by similarly manufacturing the external wall portion of the micro-lens in the photolithography and etching processes while keeping alignment relatively with such a lens portion with high accuracy. The external wall portion of the micro-lens is required to be etched in a range of 100 μm (micro meters) deep, while the lens portion is etched only in a range of 1 μm (micro meters) deep. This makes very difficult manufacturing both portions with high accuracy in a single etching process.

When a micro-lens is manufactured in two etching processes as described above, an amount of an eccentric error in the optical axis of a completed lens is affected by both accuracy of aligning the peripheral pattern of a lens in a second process with the pattern of the lens portion in a first process and a manufacturing error in a diameter of the peripheral pattern. A scanning electron microscopy (SEM) equipment or microscope with several hundred magnifications is required to measure an error in a diameter of the peripheral pattern manufactured in a substrate as a batch with accuracy in a level of submicrons particularly in a micro-lens with the lens diameter of several hundred microns. There is also a problem such as a need for more manpower and higher cost for measurement (assessment).

Patent Document 1: Japan Patent Publication Number 3696802

Patent Document 2: Japan Patent Publication Laid Open Number 2003-161811

### OBJECTS OF THE INVENTION

The present invention has been carried out under the conditions described above and has a first purpose to provide a method of enabling to assess in a simple and highly accurate manner an amount of misalignment with the optical axis caused by an error in a manufacturing process of a micro-lens.

Other purpose of the present invention is to provide a method of manufacturing a micro-lens, in which an amount of misalignment with the optical axis caused by an error in a manufacturing process of the micro-lens can be assessed in a simple and highly accurate manner.

A yet another purpose of the present invention is to provide a micro-lens, in which an amount of misalignment with the optical axis caused by an error in a manufacturing process of a micro-lens can be assessed in a simple and highly accurate manner.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

A first aspect of the present invention is applied to a micro-lens manufactured using a semiconductor substrate. A lens portion, a peripheral portion located outside the lens portion and a mark for assessment near the peripheral portion formed during a process to form the lens portion are provided.

A micro-lens of the present invention is preferably the micro-lens manufactured using a semiconductor substrate and applied to the micro-lens aligning to mount in a groove with a V-shaped cross-section formed on the semiconductor substrate for an optical module. The micro-lens according to the present invention is then provided with a lens portion, a peripheral portion located outside the lens portion and a mark for assessment near the location, where the peripheral portion contacts the groove during a process to form the lens portion.

According to the configuration of the present invention described above, a lens portion and a pattern of assessing an error are simultaneously manufactured in advance to form the peripheral portion of lens followed by visual inspection of the pattern appearance, thus allowing to easily assess whether an amount of misalignment with the optical axis is within a specification (permissible range (dimensional tolerance)). That is, an error in manufacturing the lens and the external shape of lens are not required to be measured in high accuracy.

Specifically, after a pattern mark (D-RIE TEG) to assess a dimensional error of the central portion of a lens with the external wall portion of a lens is manufactured simultaneously, the external wall portion of the lens is deeply etched and the surface of this lens is then inspected by an SEM equipment or microscope. On this occasion, for example, when a pattern mark of D-RIE TEG is deficient, this is determined as a dimension of the external wall portion of lens is manufactured smaller than the value in specification. Thus, instant determination becomes possible without fresh measurement of a lens diameter.

A second aspect of the present invention is applied to a method of assessing a micro-lens having a lens portion and a peripheral portion located outside said lens portion. In such a method, accuracy of manufacturing said micro-lens is assessed by forming a mark for assessment near said peripheral portion in the same process as formation of said lens portion when the lens portion is formed on a semiconductor substrate and observing a positional relation between the mark and the peripheral portion after completing formation of the peripheral portion.

The mark can be provided so as to contact said peripheral portion, when the peripheral portion is located inside (smaller than) or outside (larger than) the permissible range (dimensional tolerance).

The mark corresponds to the permissible range (dimensional tolerance) for the location of the peripheral portion and can be provided so that the peripheral portion contacts said mark when the peripheral portion is located inside the permissible range (dimensional tolerance).

The mark is composed of a pair of mark elements formed at a predetermined interval and the interval of a pair of such mark elements corresponds to the permissible range (dimensional tolerance) for the location of the peripheral portion, allowing to determine to be normal when the peripheral portion is located between a pair of the mark elements.

The mark can be formed at least in two locations near the peripheral portion.

The mark can be formed in a continuously elongated form along the peripheral portion.

The micro-lens can be aligned using part of the peripheral portion as a contact when mounted. In this occasion, the mark is preferably formed near a location of the contact.

The lens portion and the mark can be formed by a photolithography and etching technology using a same mask.

A third aspect of the present invention is applied to a method of assessing a micro-lens aligned to mount in a groove with a V-shaped cross-section formed on a semiconductor substrate. In this case, the micro-lens has a lens portion and a peripheral portion located outside said lens portion and contacted with the inclined inner wall of above groove. A mark for assessment is formed near the location, where the peripheral portion contacts with the groove according to the same process as formation of said lens portion, when forming the lens portion on a semiconductor substrate. After completing formation of the peripheral portion, a positional relation of the mark with the peripheral portion can be observed to assess manufacturing accuracy of said micro-lens.

The mark can be provided so as to contact the peripheral portion, when the peripheral portion is located inside (smaller than) or outside (larger than) the permissible range (dimensional tolerance).

The mark corresponds to the permissible range (dimensional tolerance) for the location of the peripheral portion and can be provided so that the peripheral portion contacts said mark, when said peripheral portion is located inside the permissible range (dimensional tolerance).

The mark is composed of a pair of mark elements formed at a predetermined interval and the interval of a pair of such mark elements corresponds to the permissible range (dimensional tolerance) for the location of the peripheral portion, allowing to determine to be normal when the peripheral portion is located between a pair of the mark elements.

The lens portion and the mark can be formed by a photolithography and etching technology using a same mask.

A fourth aspect of the present invention is applied to a method of manufacturing a micro-lens having a lens portion and a peripheral portion located outside said lens portion. In a such method, a lens portion is formed on a semiconductor substrate by a photolithography and etching technology, a mark for assessment is formed near an area, where the peripheral portion is formed in a process to form the lens portion and an external shape of the micro-lens is defined by forming the peripheral portion after forming the lens portion and the mark.

The mark can be provided so as to contact the peripheral portion, when said peripheral portion is located inside (smaller than) or outside (larger than) the permissible range (dimensional tolerance).

The mark corresponds to the permissible range (dimensional tolerance) for the location of the peripheral portion and can be provided so that the peripheral portion contacts said mark, when the peripheral portion is located inside the permissible range (dimensional tolerance).

The mark is composed of a pair of mark elements formed at a predetermined interval and the interval of a pair of such mark elements can be configured to correspond to the permissible range (dimensional tolerance) for the location of the peripheral portion. In this occasion, a pair of the mark elements is preferably provided to locate therebetween, when the peripheral portion is located inside the permissible range (dimensional tolerance).

The mark can be formed at least in two locations near the peripheral portion.

The mark can be formed in a continuously elongated form along the peripheral portion.

The micro-lens can be aligned using part of the peripheral portion as a contact when mounted. In this occasion, the mark is preferably formed near a location of the contact.

The lens portion and the mark can be formed by a photolithography and etching technology using a same mask.

A fifth aspect of the present invention is a micro-lens aligned to mount in a groove with a V-shaped cross-section formed on a semiconductor substrate and applied to a method of manufacturing the micro-lens having a lens portion and a peripheral portion located outside said lens portion and contacted with the inclined inner wall of the groove. In such a method, the lens portion is formed on a semiconductor substrate by a photolithography and etching technology, a mark for assessment is formed near the location, where the peripheral portion contacts the groove in a process to form the lens portion and an external shape of the micro-lens is defined by forming the peripheral portion after forming the lens portion and the mark.

The mark can be provided so as to contact the peripheral portion, when said peripheral portion is located inside (smaller than) or outside (larger than) the permissible range (dimensional tolerance) .

The mark corresponds to the permissible range (dimensional tolerance) for the location of the peripheral portion and can be provided so that the peripheral portion contacts said mark, when the peripheral portion is located inside the permissible range (dimensional tolerance).

The mark is composed of a pair of mark elements formed at a predetermined interval and the interval of a pair of such mark elements can be configured to correspond to the permissible range (dimensional tolerance) for the location of the peripheral portion. In this occasion, a pair of the mark elements is preferably located therebetween when the peripheral portion is located within the permissible range (dimensional tolerance).

### BRIEF DESCRIPTION OF THE DRAWINGS

FIG. 1 is a graph illustrating an effect of misalignment of a micro-lens.

FIG. 2 is a perspective view illustrating a structure of an optical communication module, to which the present invention can be applied.

FIG. 3A is a side view illustrating an appearance of an optical communication module in the present invention observed from a lateral side A (receiving side) of FIG. 2.

FIG. 3B is a side view illustrating an appearance of an optical communication module in the present invention observed from a lateral side B (transmitting side) of FIG. 2.

FIG. 4 is a plan view illustrating the optical path in the optical communication module shown in FIG. 2.

FIG. 5A is an appearance of the optical path in the optical communication module shown in FIG. 2 observed from a receiving side.

FIG. 5B is an appearance of the light path in the optical communication module shown in FIG. 2 observed from a transmitting side.

FIG. 6 is an enlarged sectional view used in describing manufacturing accuracy of a micro-lens.

FIG. 7A is a schematic view illustrating a state of alignment in a micro-lens, indicating a normal state.

FIG. 7B is a schematic view illustrating a state of alignment in a micro-lens, indicating a state of misaligning a center of a lens portion with that of a spherical portion.

FIG. 7C is a schematic view illustrating a state of alignment in a micro-lens, indicating a state, in which a large error occurs in a diameter of a peripheral portion.

FIG. 8 is a schematic plan view (enlarged plan view) illustrating a configuration of a mark of assessing a micro-lens associated with a first preferred embodiment of the present invention.

FIG. 9 is an enlarged sectional view along the direction A-A in FIG. 8.

FIG. 10 is a schematic view illustrating a method of assessing a micro-lens associated with the first preferred embodiment of the present invention.

FIG. 11 is an illustrative view illustrating a method of assessing a micro-lens associated with a second preferred embodiment of the present invention.

FIG. 12 is an illustrative view illustrating a method of assessing a micro-lens associated with a third preferred embodiment of the present invention.

FIG. 13 is a schematic plan view (enlarged plan view) illustrating a configuration of a mark of assessing a micro-lens associated with a fourth preferred embodiment of the present invention.

FIG. 14 is a schematic plan view (enlarged plan view) illustrating a configuration of a mark of assessing a micro-lens associated with a fifth preferred embodiment of the present invention.

FIG. 15 is a schematic plan view (enlarged plan view) illustrating a configuration of a mark of assessing a micro-lens associated with a sixth preferred embodiment of the present invention.

FIG. 16 is an enlarged sectional view along the direction B-B in FIG. 15.

FIG. 17 is a schematic plan view (enlarged plan view) illustrating a configuration of a mark of assessing a micro-lens associated with a seventh preferred embodiment of the present invention.

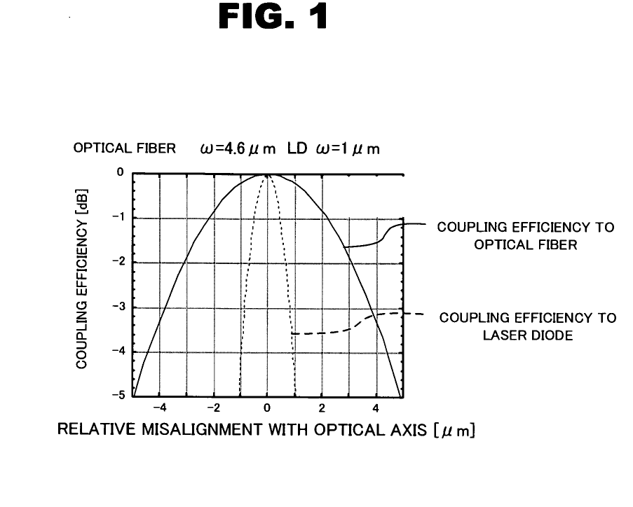

### DESCRIPTION OF REFERENCE NUMERALS

20: Lens portion
22: Peripheral portion
100: Semiconductor substrate
101: Groove of optical path on transmitting side (V-groove)
102: Groove of optical path on receiving side (V-groove)
103: Light emitting element (LD)
104: Silicon lens on transmitting side
105: Silicon lens on receiving side
106: Light receiving element (PD)
124, 224, 324, 424, 524, 624 and 724: Marks for assessment (D-RIE TEG)

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

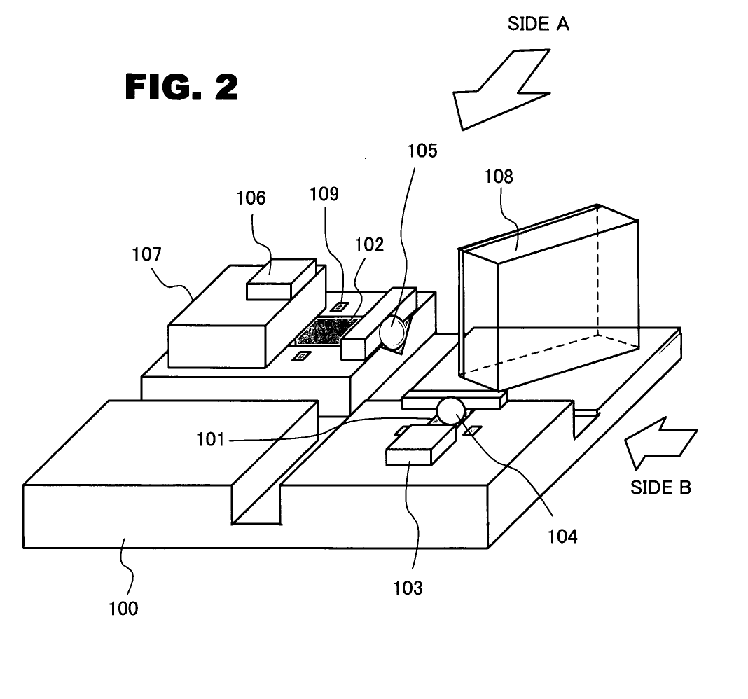

FIG. 2 illustrates a structure of a single core two-way optical communication module, to which the present invention can be applied. In a module shown in FIG. 2, an optical transmission unit (103), an optical receiving unit (106) and a wavelength filter (108) are mounted together on single substrate. This realizes miniaturization and cost-reduction in the optical communication module.

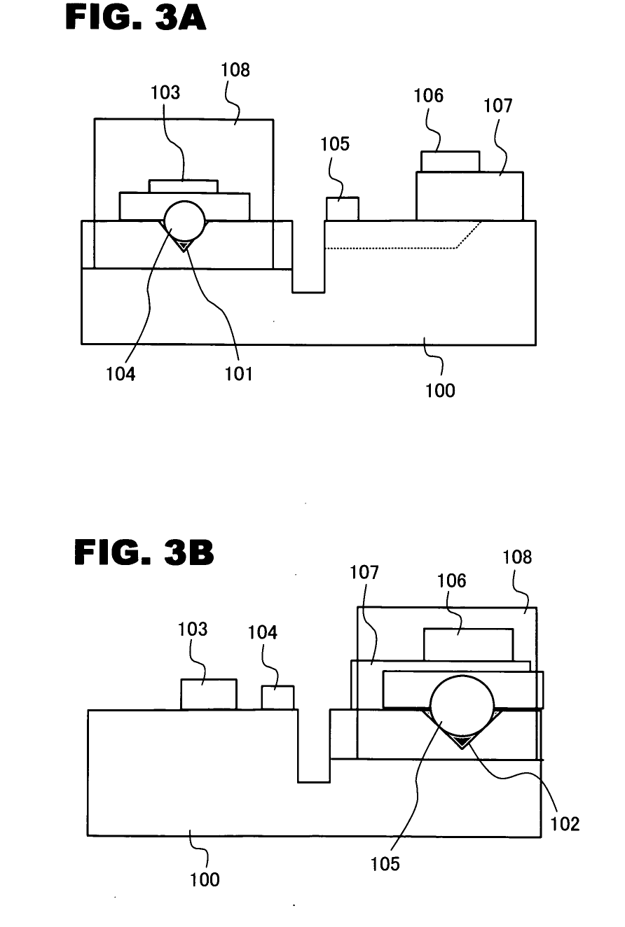

FIGS. 3A and 3B are side views illustrating an appearance observed from side A (receiving side) and side B (transmitting side) of FIG. 2, respectively. In FIGS. 2, 3A and 3B, an alignment mark 109 used for aligning with an element during mounting and the V-grooves 101 and 102 with a V-shaped cross-section when observed from a lateral direction are formed by anisotropic etching on a silicone substrate 100 as a support substrate. A laser chip (LD) 103 emitting the light for transmission, a micro-lens on transmitting side 104, a micro-lens on receiving side 105, a light receiving element (PD) converting an optical signal to an electric signal 106, a glass element 107 and a wavelength filter 108 are mounted on such a substrate 100 to manufacture an optical communication module.

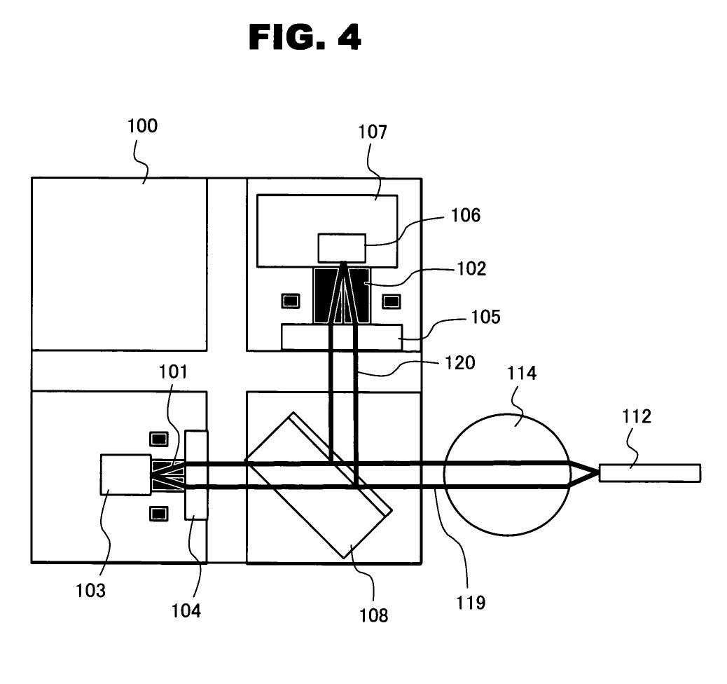

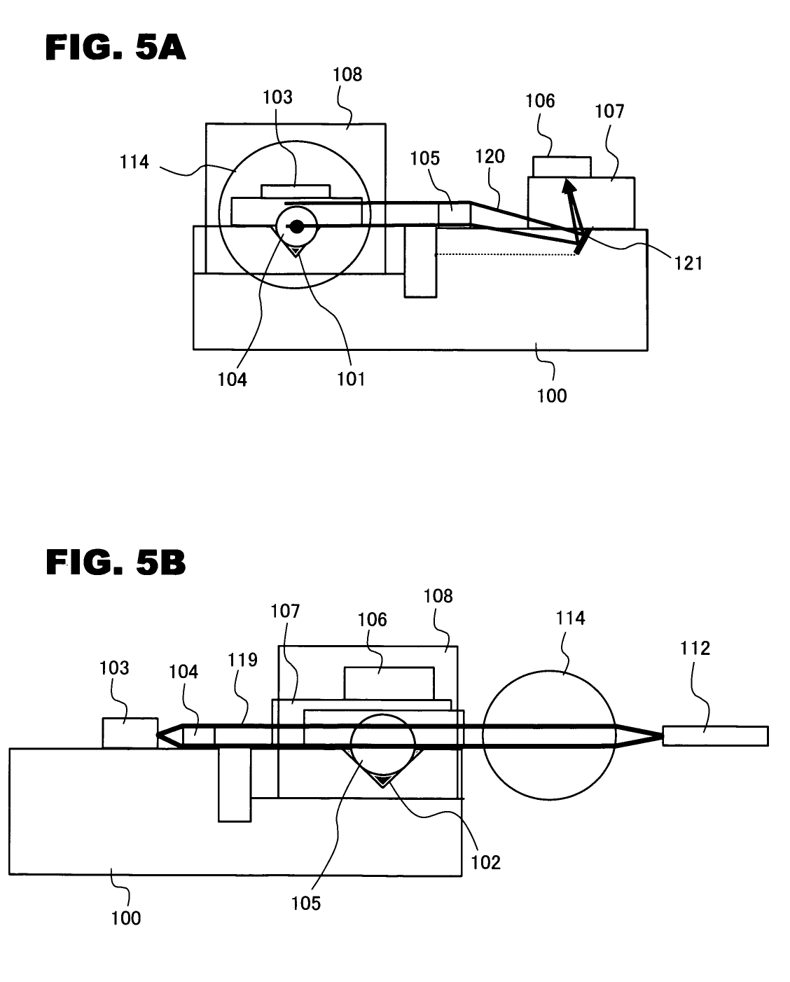

A method of two-way communication by the optical communication module shown in FIG. 2 is next described. FIG. 4 is a plan view illustrating the optical path of the optical communication module shown in FIG. 2. FIGS. 5A and 5B are side views illustrating the optical path of the optical communication module shown in FIG. 2 divided into a receiving side and a transmitting side, respectively. As shown in FIGS. 4, 5A and 5B, sent light 119 emitted from LD 103 in light transmission is collimated by a nearest micro-lens 104 to pass through a wavelength filter 108 and then converge by a ball lens 114 to an optical fiber 112.

The received light 120 emitted from the optical fiber 112 in receiving passes through a ball lens 114 and is then refracted by 90 degrees at a reflective coating of the wavelength filter 108 to reach the micro-lens 105 on receiving side. After the received light 120 is diffracted at the lens 105, it passes through an inside of the V-groove 102 on receiving side and is reflected at a reflection plane (not shown) formed at an end plane of the V-groove 102 to reach through the glass element 107 a light acceptance surface of PD 106 mounted on a top surface thereof.

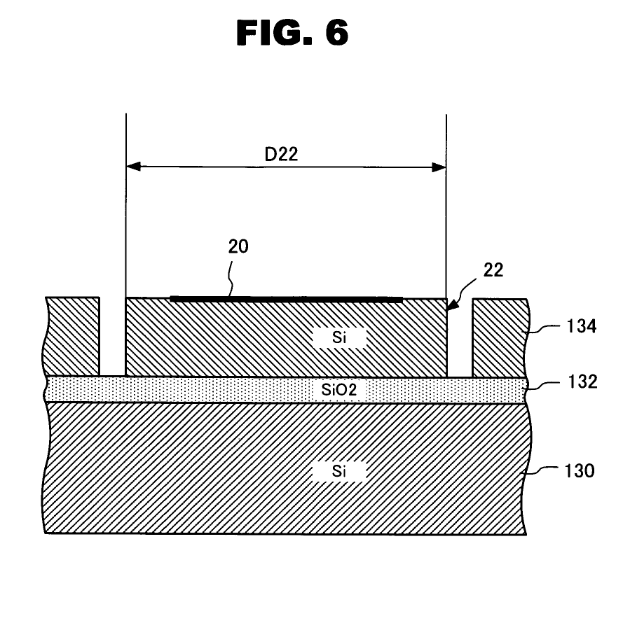

FIG. 6 is an enlarged sectional view used for describing manufacturing accuracy of a micro-lens. As shown in FIG. 6, micro-lens (104 and 105) associated with the present invention can be manufactured using a silicon-on-insulator (SOI) substrate. The micro-lens unit is formed on an SOI layer 134, in which a peripheral portion 22 is formed with D-RIE on a wafer to define the area in each micro-lens. A symbol 20 in the figure indicates the lens portion of micro-lens. After a micro-lens is assessed in a state illustrated in FIG. 6 (in a state of a wafer), each micro-lens is detached from an SOI substrate.

In manufacturing of a micro-lens, a silicon dioxide film 132 is at first formed on a silicon substrate 130. The silicon dioxide film 132 serves as an etch stopper in a post-process. A device-forming layer 134 consisted of a silicon substrate (SOI substrate) is next formed on the oxide film 132. The device-forming layer 134 is the part serving as a lens element in a post-process. The device-forming layer 134 is formed in thickness substantially same as the lens element in the direction of the optical axis, which forms a final shape in the process described below.

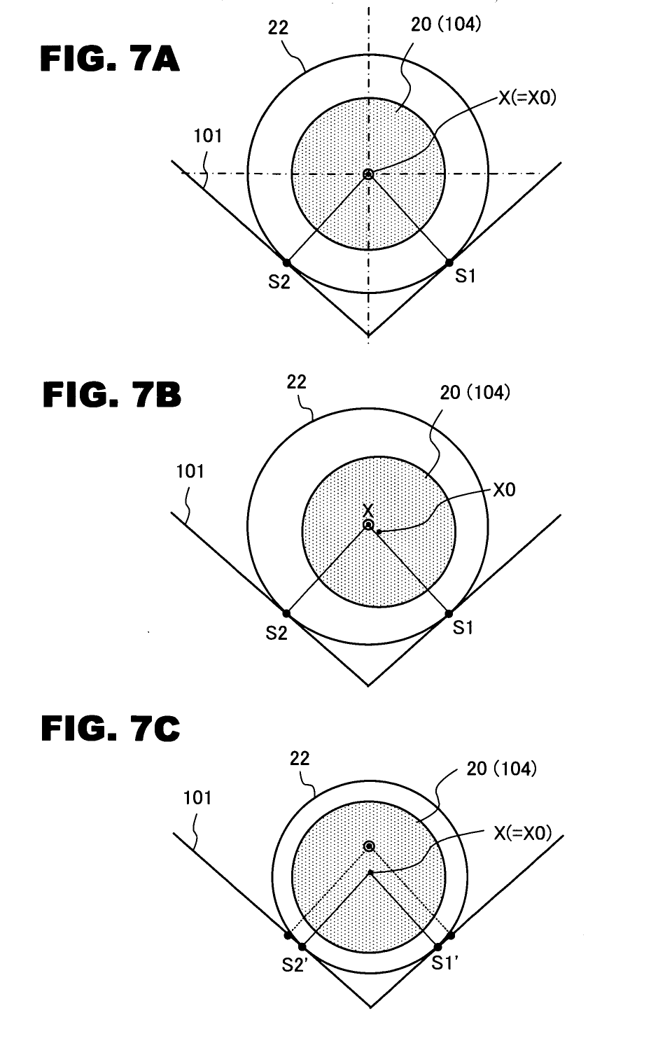

FIGS. 7A to 7C are illustrative views illustrating a state of aligning a micro-lens, indicating a normal state in FIG. 7A, a state of misaligning a center of a lens portion with that of a peripheral portion in FIG. 7B and a state, where a large error in a diameter of the peripheral portion occurs in FIG. 7C, respectively.

As shown in FIG. 7A, a lens portion 20 (104) and a peripheral portion 22 of a micro-lens are concentric (X=X0) and a distance from contacts S1 and S2 between a V-groove and a peripheral portion of the micro-lens to a center of the lens becomes correct when a diameter of the peripheral portion 22 is accurately manufactured. As a result, the micro-lenses (104 and 105) on a semiconductor substrate 100 (FIG. 2) are accurately aligned with the grooves (101 and 102). Accurate alignment with the grooves (101 and 102) allows the optical axis of the micro-lens to accurately align with the optical axis of optical elements such as a light emitting element (103), a light receiving element (106) and the like.

In a case shown in FIG. 7B, while the external shape of a peripheral portion 22 (diameter, D22) of a micro-lens is manufactured accurately, a center X0 of a lens portion 20 (104) is misaligned with a center X of the peripheral portion 22. Such a. state causes misalignment with a distance from the contacts S1 and S2 to a center of the lens portion 20, even if the peripheral portion 22 is accurately aligned with the grooves (101 and 102) on a semiconductor substrate 100 (FIG. 2). That is, a center X0 of the lens portion 20 is not accurately aligned with the groove 101 to misalign the optical axis of the micro-lens with the optical axis of the light emitting element (103) and of the light receiving element (106).

In a case shown in FIG. 7C, while a center X0 of a lens portion 20 is coincident with a center X of a peripheral portion 22 (X0=X), an external shape (D22) of the peripheral portion is shaped smaller than a preset value. Such a state does not allow accurate alignment of the peripheral portion 22 with the grooves (101 and 102) on a semiconductor substrate 100 (FIG. 2), misaligning a distance from the contacts S1 and S2 to a center of the lens portion 20. That is, a center X0 of the lens portion 20 is not accurately aligned with the groove 101 to misalign the optical axis of the micro-lens with the optical axis of the light emitting element (103) and of the light receiving element (106).

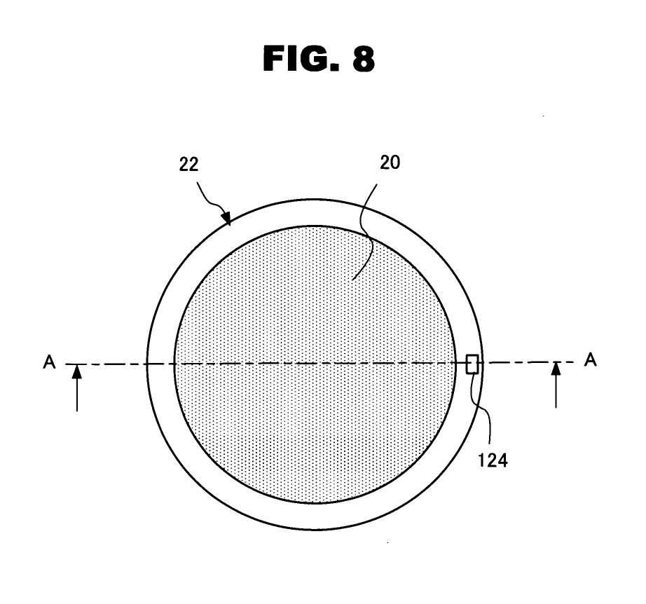

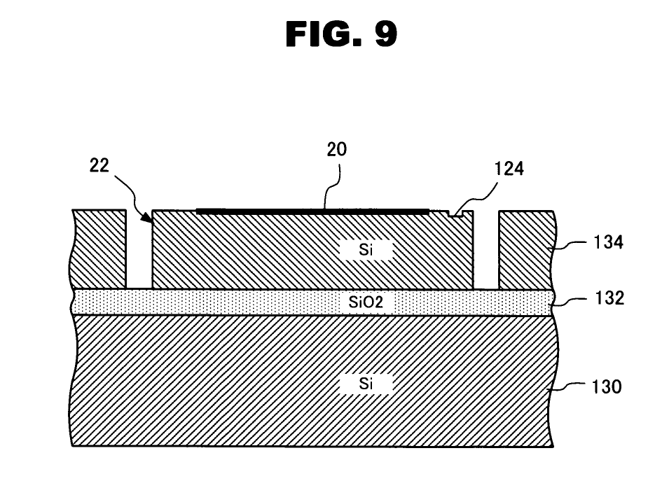

FIG. 8 is a schematic plan view (enlarged plan view) illustrating a configuration of a mark for assessing a micro-lens associated with a first preferred embodiment of the present invention. FIG. 9 is an enlarged sectional view along the direction A-A in FIG. 8. As described above, a micro-lens associated with the present invention is manufactured using a semiconductor substrate and aligned to mount in the grooves (101 and 102) with a V-shaped cross-section formed on a semiconductor substrate for an optical module. The micro-lens is provided with a lens portion 20 serving as a lens, a peripheral portion 22 located outside the lens portion 20 and a mark 124 for assessment formed near a location, where the peripheral portion 22 contacts the grooves (101 and 102) in a process to form the lens portion 20.

In the present embodiment, a lens portion 20 has a circular shape, and is composed of a diffraction optical element. The lens portion 20 can be formed with a computer-generated hologram (CGH) element, which is one of diffraction optical elements. As well known heretofore, in a CGH element, a photomask pattern required to obtain desired optical properties is obtained using a computer from a function of optical path difference for an optical element exhibiting desired optical properties, followed by an etching treatment at a desired location of an optical substrate using such a mask pattern to form a diffraction type optical element exhibiting desired optical properties. An etching treatment at a desired location of the optical substrate using a photomask pattern thus enables to form the lens portion 20 exhibiting desired diffraction optical properties.

A lens portion 20 is not limited to have a diffraction type lens surface described above, but may have a refraction type lens surface. The lens portion 20 is also not limited to have a circular shape described above, but may be formed in a desired planar shape.

As shown in FIG. 9, in manufacturing a micro-lens, a silicon dioxide film 132 is formed on a silicon substrate 130, to form an SOI layer thereon, followed by forming a lens portion on a so-called SOI substrate.

A device-forming layer 134 is formed in thickness substantially same as a lens element in a direction of the optical axis, which forms a final shape in the process described below. A crystalline substrate such as a crystalline silicon substrate can be used as a device-forming layer 134, when incident light is light with wavelength, for example, 1.3 μm (micro meters) or 1.5 μm (micro meters).

A lens portion 20 is formed in an n×m array at a regular interval (not shown) on a top surface of a device-forming layer 134 in a state of a wafer. The lens portion may be formed in a stepwise shape as a Fresnel lens. The Fresnel lens can be formed by repeating photolithography and etching several times. A method described in Japan Patent Publication Laid Open Number 2006-343461 can be used to form a stepwise shape in the lens portion 20.

In FIG. 9, for example, an interval between adjacent micro-lenses themselves (width in an open space of peripheral portion 22) and thickness of a device-forming layer 134 can be about 10 μm (micro meters) and about 100 μm (micro meters), respectively. Eight thousands to nine thousands of micro-lenses can be manufactured at once on a wafer, for example, in a case of 6 inches.

It is important to form a mark 124 simultaneously in a step forming a lens portion 20. That is, a pattern for the mark 124 is formed on the same mask as a mask used in formation of the lens portion 20. When a plurality of processes to form the lens portion 20 is involved, a mark 124 is formed in any one of the processes. The mark 124 is formed simultaneously in a step forming the lens portion 20, so that a relation of relative position of the lens portion 20 with the mark 124 can be accurately defined. In the present embodiment, the mark 124 is now shaped concave by etching.

In this embodiment, a mark 124 is configured so as to contact a value of specified dimension for a peripheral portion 22. The mark 124 is provided so as to contact said peripheral portion 22 when the peripheral portion 22 is located inside (smaller than) the permissible range (dimensional tolerance) relative to a lens portion 20.

When an external shape of a micro-lens is manufactured, photolithography is next used to fabricate a pattern on a photoresist applied to a device-forming layer 134 into a shape of a lens element. This resist is used as an etching mask for dry etching to transfer the shape of this photoresist onto a device-forming layer 134, manufacturing an external shape of a peripheral portion 22 of a micro-lens. A reactive ion etching (RIE) method, an inductively coupled plasma (ICP)-Bosch method (silicon deep-etching process) and the like can be used as a drying etching technique used herein. In this time, the device-forming layer 134 fabricated to a pattern is an SOI substrate, which is etched deep enough to reach to an oxide film 132, for example, by the ICP-Bosch method.

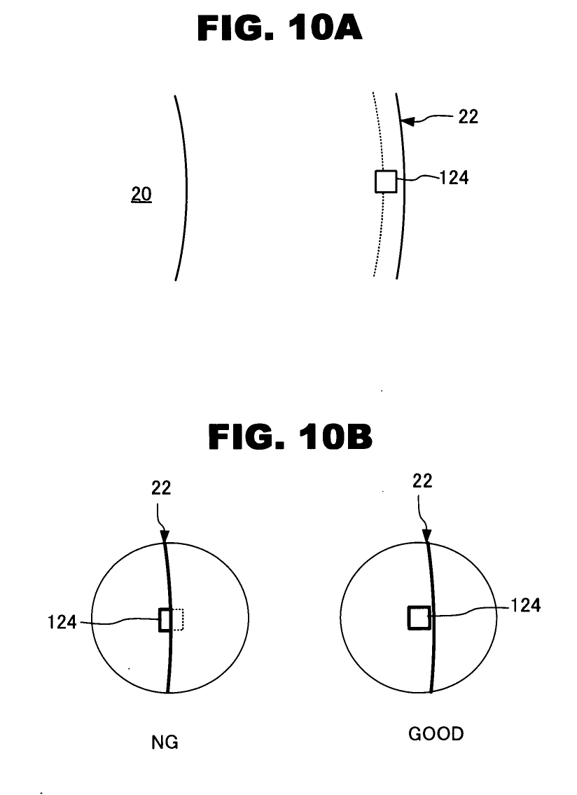

FIG. 10 is an illustrative view illustrating a method of assessing a micro-lens associated with the first preferred embodiment of the present invention. In the present embodiment, as shown in FIG. 10A, a mark 124 is configured so as to contact a value of specified dimension for a peripheral portion 22. As shown in a left figure of FIG. 10B, when the peripheral portion 22 is located inside (smaller than) a specified value, the peripheral portion 22 leads to traverse the mark 124 and only part of the mark 124 is observed. On the other hand, as shown in a right figure of FIG. 10B, when the peripheral portion 22 is located to match with the specified value, the peripheral portion 22 leads to mostly contact the mark 124 and an entire mark 124 can be observed. The mark 124 can be observed by an SEM equipment or microscope. It is required only to determine whether there is any defect in the mark 124 and a diameter of the lens is not required to be measured.

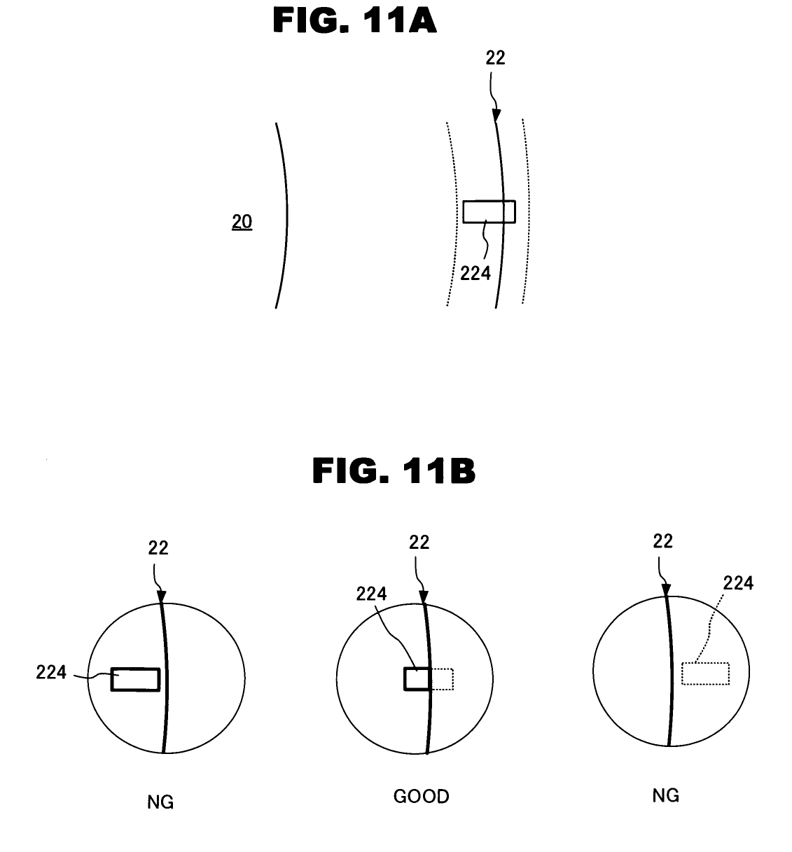

FIG. 11 illustrates a method of assessing a micro-lens associated with a second preferred embodiment of the present invention. In the present embodiment, since an entire structure of an optical module and a micro-lens is similar to the first preferred embodiment described above, duplication of description is omitted, but a shape and a configuration of a mark 224, which is a distinguished portion are described in detail.

As shown in FIG. 11A, in the present embodiment a lateral width of a mark 224 for assessing a dimension of a lens corresponds to the permissible range (dimensional tolerance) for a location of a peripheral portion 22 relative to a lens portion 20 and the peripheral portion 22 is provided so as to contact (traverse) with said mark 224 when the peripheral portion 22 is inside said permissible range (dimensional tolerance). As shown in a middle figure of FIG. 11B, it is determined to be normal when the peripheral portion 22 traverses the mark 224. On the other hand, as shown in a left figure and a right figure of FIG. 11B, it is determined to be dimensionally abnormal when the peripheral portion 22 does not traverse the mark 224 at all.

According to the present embodiment, both cases where an external shape of a lens is too large or too small can be detected as being dimensionally abnormal. A mark 224 in a normal state is detected smaller than a design value when observed by a microscope and the like. A lens is determined to be dimensionally abnormal when the mark 224 is observed as big as a design value (left from FIG. 11B) or the mark 224 is not observed at all (right from FIG. 11B).

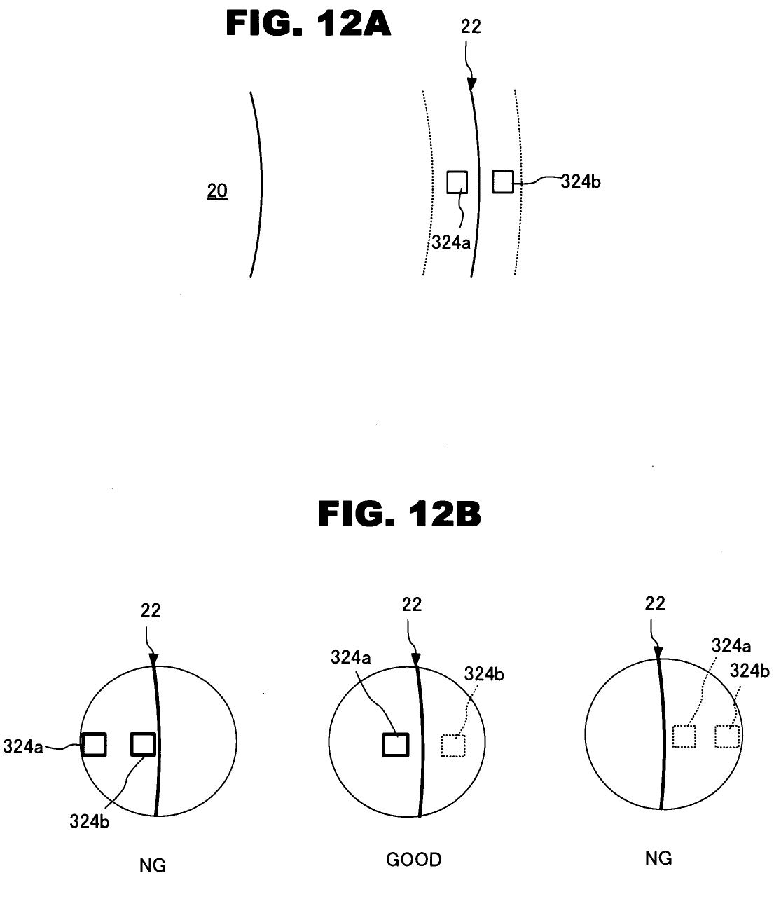

FIG. 12 illustrates a method of assessing a micro-lens associated with a third preferred embodiment of the present invention. In the present embodiment, since an entire structure of an optical module and a micro-lens is similar to the first preferred embodiment described above, duplication of description is omitted, but a shape and a configuration of the marks 324 (324a and 324b), which are distinguished portions are described in detail.

In the present embodiment, a mark 324 for assessing an external shape of a lens is consisted of a pair of mark elements 324a and 324b formed at a predetermined interval as shown in FIG. 12A. An interval of a pair of these mark elements 324a and 324b corresponds to the permissible range (dimensional tolerance) for the location of a peripheral portion 22. As shown in a middle of FIG. 12B, it is determined to be normal when the peripheral portion 22 is located between a pair of the mark elements 324a and 324b. On the other hand, it is determined to be dimensionally abnormal when the peripheral portion 22 is formed outside a pair of the mark elements 324a and 324b (left figure) or the peripheral portion 22 is formed inside a pair of the mark elements 324a and 324b (right figure).

According to the present embodiment, both cases where an external shape of a lens is too large or too small can be detected as being dimensionally abnormal similar to the second preferred embodiment described above. Only a mark element 324a is detected in a normal state when observed by a microscope and the like as shown in a middle of FIG. 12B. When an external shape of a micro-lens is abnormal, both mark elements 324a and 324b are observed as shown in a left figure of FIG. 12B or neither one is observed as shown in a right figure of FIG. 12B. Furthermore, according to the present embodiment, the peripheral portion 22 does not essentially overlap with the mark (324a and 324b) provided by etching, so that an error caused by unevenness in the layers during photolithography can be prevented.

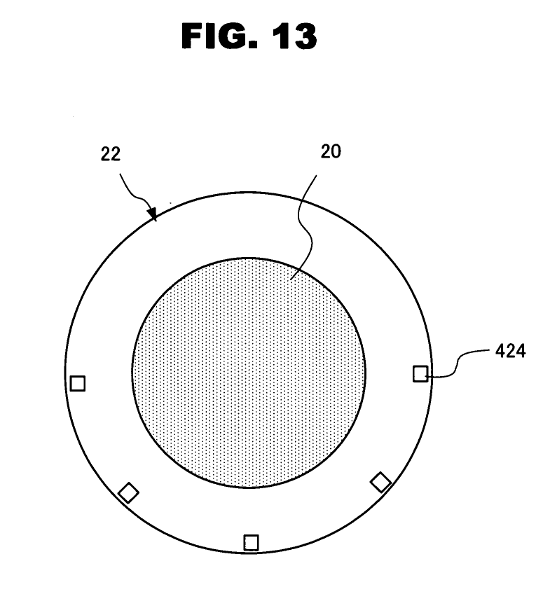

FIG. 13 is a schematic plan view (enlarged plan view) illustrating a configuration of a mark for assessing a micro-lens associated with a fourth preferred embodiment of the present invention. In the present embodiment, since an entire structure of an optical module and a micro-lens is similar to the first preferred embodiment described above, duplication of description is omitted, but a configuration of a mark 424, which is a distinguished portion is described in detail. In the present embodiment, the mark 424 for assessing an external shape of a micro-lens is provided at a plurality of locations (5 locations). A configuration of the mark 424 itself can use any one of the configurations and methods used in the first to third preferred embodiments described above. The mark 424 in this figure is formed one-by-one at a location for each assessment (observation), but a pair of marks in the third preferred embodiment may also be used.

Two locations among five locations of the mark 424 are preferably near the contacts S1 and S2 with the V-grooves (101 and 102). This can realize effectively controlling dimensional accuracy of a lens.

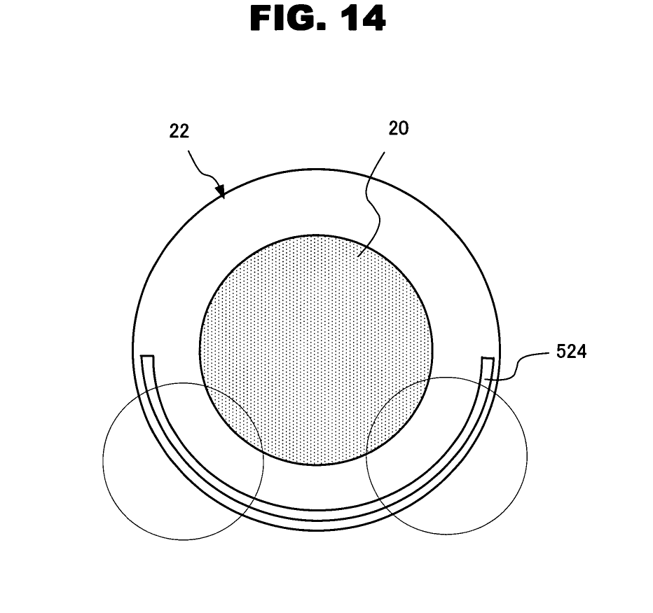

FIG. 14 is a schematic plan view (enlarged plan view) illustrating a configuration of a mark for assessing a micro-lens associated with a fifth preferred embodiment of the present invention. In the present embodiment, since an entire structure of an optical module and a micro-lens is similar to the first preferred embodiment described above, duplication of description is omitted, but a shape and configuration of a mark 524, which is a distinguished portion are described in detail. In the present embodiment, the mark 524 for assessing an external shape of a micro-lens uses a continuously elongated mark along a peripheral portion 22.

A method of assessing an external shape of a micro-lens using a mark 524 can use any one used in the first to third preferred embodiments described above. The mark 524 in this figure is a single continuous form, but may use two marks parallel to each other as in the third preferred embodiment. In the present embodiment, the continuous mark 524 contains contacts S1 and S2 with the V-grooves (101 and 102), enabling to realize effectively controlling dimensional accuracy of a lens. For example, an area near contacts (S1 and S2) (encircled area) is preferably observed when the peripheral portion 22 is observed with a microscope and the like.

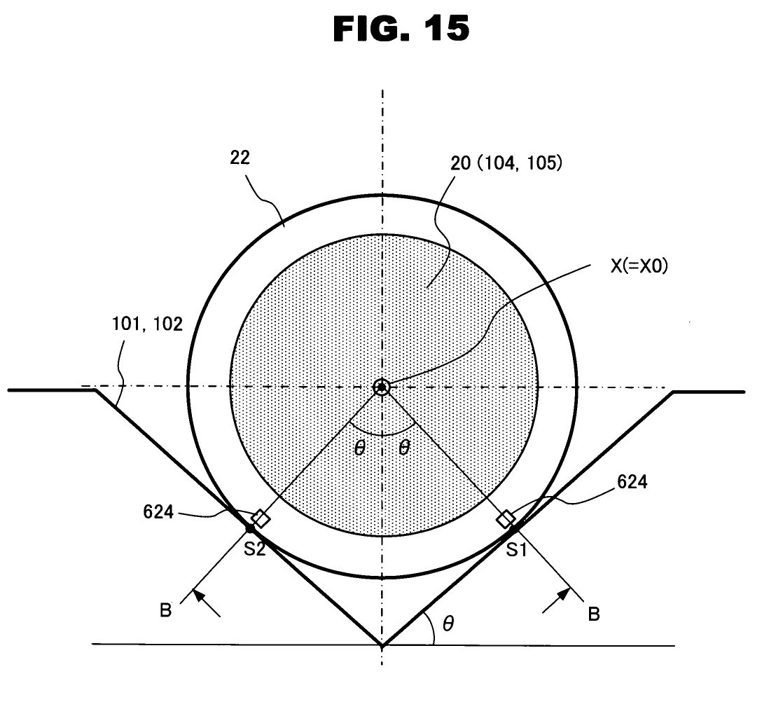

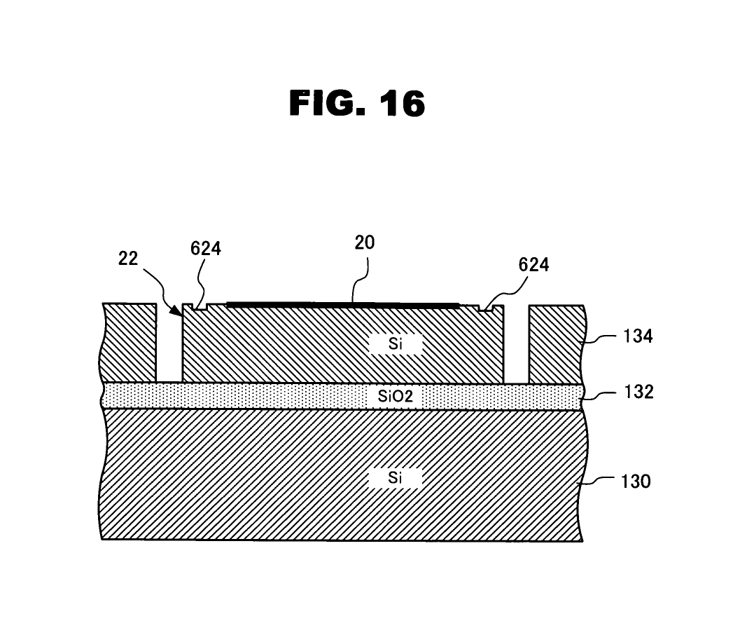

FIG. 15 is a schematic plan view (enlarged plan view) illustrating a configuration of a mark for assessing a micro-lens associated with a sixth preferred embodiment of the present invention. FIG. 16 is an enlarged sectional view along the direction B-B in FIG. 15. In the present embodiment, since an entire structure of an optical module and a micro-lens is similar to the first preferred embodiment described above, duplication of description is omitted, but a shape and configuration of a mark 624, which is a distinguished portion are described in detail. The present embodiment assumes the case, where a micro-lens is mounted in the V-grooves (101 and 102) provided on a semiconductor substrate shown in FIG. 2. In the present embodiment, when an angle of a side wall of the V-grooves (101 and 102) is θ, a line in a radial direction deviated by angle θ from a center of a lens is extended to provide a mark 624 for assessment around the intersections (S1 and S2) with the side wall of a lens.

In the present embodiment, a cylindrical outer wall (22) of a micro-lens contacts an inner side surface of the V-grooves (101 and 102) at two locations (S1 and S2). Thus, it is good enough for a side wall (22) of a lens to satisfy a design specification only around said contacts (S1 and S2). In the present embodiment, a mark 624 for assessment is provided near the contacts (S1 and S2) between this external wall (22) of a lens and an inner side surface of the V-grooves (101 and 102) to realize effectively controlling dimensional accuracy of a lens. A configuration of the mark 624 itself can use any one of the configurations and methods in the first to third preferred embodiments described above.

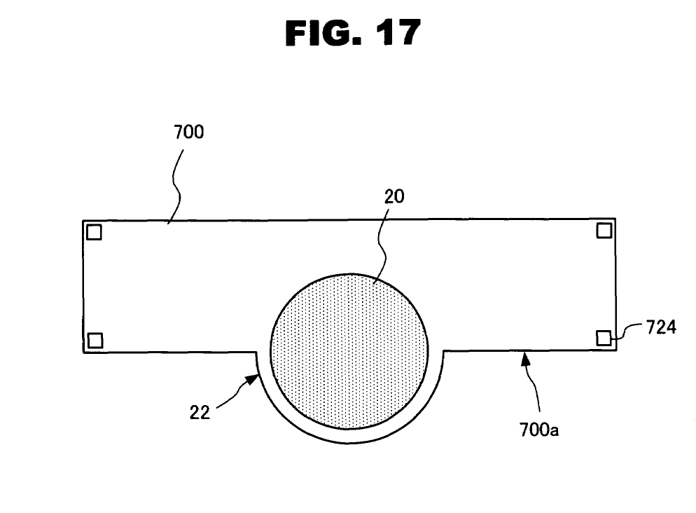

FIG. 17 is a schematic plan view (enlarged plan view) illustrating a configuration of a mark for assessing a micro-lens associated with a seventh preferred embodiment of the present invention. The present embodiment provides D-RIE TEG (mark for assessment) 724 at four corners in a micro-lens provided with a support 700 for mounting in order to validate accuracy of manufacturing said support 700. A mark for assessing an external shape of a micro-lens may be additionally formed near a peripheral portion 22 of a micro-lens similarly to each embodiment described above.

An undersurface 700a of a support 700 contacts a surface of a semiconductor substrate 100 (FIG. 2) at an external portion of the V-grooves (101 and 102). A location to form a mark 724 may be at the very least two on the undersurface 700a in order to improve accuracy of aligning a micro-lens.

In the present embodiment, a support (handling portion) 700 having, for example, a length of 250 to 300 μm (micro meters), is integrally formed on one side of a circular lens portion 20. The support 700 is integrally formed on an edge of an lens portion 20 so as to surround an upper half of said edge at an intermediate section between both ends of the support. The support 700 extends linearly in lateral direction such that it is bilaterally symmetrical with respect to a hypothetical plane passing through an optical axis of a lens portion 20, that is, a vertical plane. The support is formed in a rectangular cross-sectional shape as a whole having a dimension in height H, for example, of 100 to 200 μm (micro meters) and a dimension in lateral direction, for example, of 100 to 200 μm (micro meters). An arced peripheral portion 22 along an outer edge of a lens portion 20 is integrally formed in an opposite side of the support 700 in the edge of said lens portion 20.

In the present embodiment, not only a mark on a lens section mounted on the V-grooves (101 and 102) but also a mark 724 for validating accuracy of manufacturing a support 700 are provided to enable improving accuracy of mounting a micro-lens as a whole. A configuration of the mark 724 itself may use any one of the configurations and methods in the first to third preferred embodiments described above.

What is claimed is:

1. A micro-lens manufactured using a semiconductor substrate, provided with
a lens portion;
a peripheral portion located outside the lens portion and
a mark for assessment formed near the peripheral portion during a process to form the lens portion.

2. The micro-lens according to claim 1, wherein
the mark is provided so as to contact with the peripheral portion, when said peripheral portion is located inside (smaller than) or outside (larger than) a permissible range (dimensional tolerance).

3. The micro-lens according to claim 1, wherein
the mark corresponds to a permissible range (dimensional tolerance) for the location of the peripheral portion and is provided so that the peripheral portion contacts said mark when the peripheral portion is inside the permissible range (dimensional tolerance).

4. The micro-lens according to claim 1, wherein
the mark is composed of a pair of mark elements formed at a predetermined interval and the interval of a pair of these mark elements corresponds to a permissible range (dimensional tolerance) for the location of the peripheral portion and,
wherein the pair of mark elements are provided so as to locate therebetween when the peripheral portion is inside the permissible range (dimensional tolerance).

5. The micro-lens according to claim 1, wherein
the mark is formed at least in two locations near the peripheral portion.

6. The micro-lens according to claim 1, comprising
the feature with forming the said mark along said peripheral portion in a continuously elongated form.

7. The micro-lens according to claim 1, wherein
the micro-lens has a configuration to align part of said peripheral portion as a contact when mounted on a semiconductor substrate,
the mark is formed near the location to serve as the contact.

8. A micro-lens manufactured using a semiconductor substrate, comprising:
a lens portion,
a peripheral portion located outside the lens portion and
a mark for assessment formed near the peripheral portion during a process to form the lens portion, in a micro-lens aligning to mount in a groove with a V-shaped cross-section formed on a semiconductor substrate for an optical module.

9. The micro-lens according to claim 8, wherein
the mark is provided so as to contact the peripheral portion, when the location of said peripheral portion is located inside (smaller than) or outside (larger than) a permissible range (dimensional tolerance).

10. The micro-lens according to claim 8, wherein
the mark corresponds to a permissible range (dimensional tolerance) for the location of the peripheral portion and is provided so that the peripheral portion contacts said mark when the peripheral portion is inside the permissible range (dimensional tolerance).

11. The micro-lens according to claim 10, wherein
the mark is composed of a pair of mark elements formed at a predetermined interval and the interval of a pair of these mark elements corresponds to a permissible range (dimensional tolerance) for the location of the peripheral portion and,
the pair of mark elements are provided so as to locate therebetween when the peripheral portion is inside the permissible range (dimensional tolerance).
